(19) United States
(12) Patent Application Publication
(10) Pub. No.: US 2026/0282672 A1
(43) Pub. Date: Sep. 17, 2026

(54) DISPLAY DEVICE

(71) Applicant: LG Display Co., Ltd., Seoul (KR)

(72) Inventors: Hye-Jeong PARK, Paju-si (KR); Seung-Cheol YOU, Paju-si (KR); Ui-Hyeon JEONG, Paju-si (KR); Won-Rae KIM, Paju-si (KR)

(73) Assignee: LG Display Co., Ltd., Seoul (KR)

(21) Appl. No.: 19/426,715

(22) Filed: Dec. 19, 2025

(30) Foreign Application Priority Data
Mar. 11, 2025 (KR) 10-2025-0031234

(51) Int. Cl. H10K 59/126; H10D 86/40; H10D 86/60; H10K 59/121; H10K 59/122; H10K 59/40; H10K 59/80

(52) U.S. Cl. CPC H10K 59/126; H10K 59/1213; H10K 59/122; H10K 59/40; H10K 59/8792; H10D 86/423; H10D 86/60

(57) ABSTRACT

A display device includes a substrate; an emission area and a non-emission area; a light-emitting diode in the emission area over the substrate and including a first electrode, a light-emitting layer, and a second electrode; a pixel defining layer in the non-emission area over the substrate; a first light-blocking part over the pixel defining layer; and a second light-blocking part over the first light-blocking part. The pixel defining layer has a light-absorbing property. Each of the first light-blocking part and the second light-blocking transmits linearly polarized light having a polarization direction that is aligned with a transmission axis direction, and reflects or absorbs linearly polarized light having a polarization direction that is perpendicular to the transmission axis direction.

### CROSS-REFERENCE TO RELATED APPLICATION

This application claims the benefit of and priority to Korean Patent Application No. 10-2025-0031234 filed in the Republic of Korea on Mar. 11, 2025, the entire contents of which are hereby expressly incorporated by reference into the present application for all purposes.

### BACKGROUND

### 1. Technical Field

The present disclosure relates to a display device, and particularly to, for example, without limitation, a display device capable of preventing deterioration of display quality and differences in visibility due to reflection of the external light.

### 2. Description of Related Art

Display devices, such as TVs, monitors, smartphones, tablet PCs, and laptops, can display images in a variety of formats and forms.

Display devices can include display panels with a plurality of light-emitting elements or liquid crystals for displaying images and transistors for controlling the operation of each light-emitting element or liquid crystal. These display devices can display the desired image through the plurality of light-emitting elements or liquid crystals.

Light-emitting display devices including light-emitting diodes, as one of the display devices, can be rapidly developed in technology. The light-emitting display devices can be categorized into organic light-emitting display devices, which utilize organic light-emitting materials, and inorganic light-emitting display devices, which utilize inorganic light-emitting materials.

To minimize reflection of the external light, the light-emitting display devices can incorporate a polarizing plate on a display surface thereof. Recently, various research and development efforts can be conducted to improve the reliability and quality of the display devices.

The description of related art should not be considered prior art merely because it is mentioned in or associated with this section. The description of related art includes information that describes one or more aspects of the subject technology, and the description in this section does not limit the scope of the present disclosure.

### SUMMARY

Accordingly, embodiments of the present disclosure are directed to a display device that substantially obviates one or more of the problems due to limitations and disadvantages of the related art.

Various embodiments of the present disclosure provide a display device capable of implementing a sense of unity by having the same reflectance and reflection visibility of a display area and a non-display area.

Various embodiments of the present disclosure provide a display device capable of achieving structural simplification.

Various embodiments of the present disclosure provide a display device capable of minimizing stains caused by reflection of the external light while maintaining/improving luminance (preventing a decrease in luminance).

Various embodiments of the present disclosure provide a display device capable of improving flexibility and applicable to a foldable product with a foldable display area.

Various embodiments of the present disclosure provide a display device capable of omitting a polarizing plate.

Various embodiments of the present disclosure provide a display device with low reflection and low power consumption.

The aspects of the present disclosure are not limited to those described above, and other technical aspects can be inferred from the following embodiments.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, in one or more aspects, a display device includes a substrate; an emission area and a non-emission area; a light-emitting diode in the emission area over the substrate and including a first electrode, a light-emitting layer, and a second electrode; a pixel defining layer in the non-emission area over the substrate; a first light-blocking part over the pixel defining layer; and a second light-blocking part over the first light-blocking part, wherein the pixel defining layer has a light-absorbing property, and wherein each of the first light-blocking part and the second light-blocking part is configured to transmit linearly polarized light having a polarization direction that is aligned with a transmission axis direction, and to reflect or absorb linearly polarized light having a polarization direction that is perpendicular to the transmission axis direction.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a schematic cross-sectional view of a display device according to a first embodiment of the present disclosure;

FIG. 2(a) to 2(d) are schematic plan views of a display device according to the first embodiment of the present disclosure;

FIG. 3 is a schematic cross-sectional view of the display device according to the first embodiment of the present disclosure;

FIG. 4 is a schematic perspective view of the first light-blocking part according to an embodiment of the present disclosure;

FIG. 5 is a schematic view illustrating the configuration of the second light-blocking part according to an embodiment of the present disclosure;

FIG. 6 is a schematic view showing a path of the external light of the display device according to the first embodiment of the present disclosure;

FIG. 7 is a schematic cross-sectional view of a display device according to a second embodiment of the present disclosure;

FIG. 8 is a schematic view showing a path of the external light of the display device according to the second embodiment of the present disclosure;

FIG. 9 is a schematic cross-sectional view of a display device according to a third embodiment of the present disclosure;

FIG. 10 is a schematic exploded perspective view of a display module according to an embodiment of the present disclosure;

FIG. 11 is a schematic cross-sectional view of a display module according to an embodiment of the present disclosure; and

FIG. 12 is a schematic plan view of a display module according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components may be present between A and B, unless explicitly specified as “A is in direct contact with B.”

Although the terms first, second, and the like are used to describe various components, these components (e.g., layers, films, components, electrodes, structures, transistors, sections, members, parts, regions, areas, portions, steps, operations, and/or the like) should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like. A term, such as a part, may apply to, for example, a component, an element, a device, or a structure, unless stated otherwise.

Features of various embodiments of the present disclosure can be partially or entirely united or combined with each other, technically various interlocking and driving are possible, and each of the embodiments can be independently implemented with respect to each other or implemented together in a related relationship.

Unless otherwise stated, transistors constituting a pixel circuit of the present disclosure can include at least one of an oxide thin film transistor (Oxide TFT), an amorphous silicon TFT (a-Si TFT), and a low temperature poly silicon TFT (LTPS TFT).

The following embodiments will be described focusing on an organic light-emitting display device. However, embodiments of the present disclosure are not limited to light-emitting display devices, and can be applied to inorganic light-emitting display devices including inorganic light-emitting materials and micro LED display devices. For example, embodiments of the present disclosure can also be applied to quantum dot display devices. That is, the display device of the present disclosure can be a light-emitting display device including an organic light-emitting diode, a quantum dot light-emitting display device including a quantum dot light-emitting diode, or a micro LED display device including a micro-LED.

Hereinafter, exemplary embodiments of the present disclosure will be described in detail with reference to accompanying drawings.

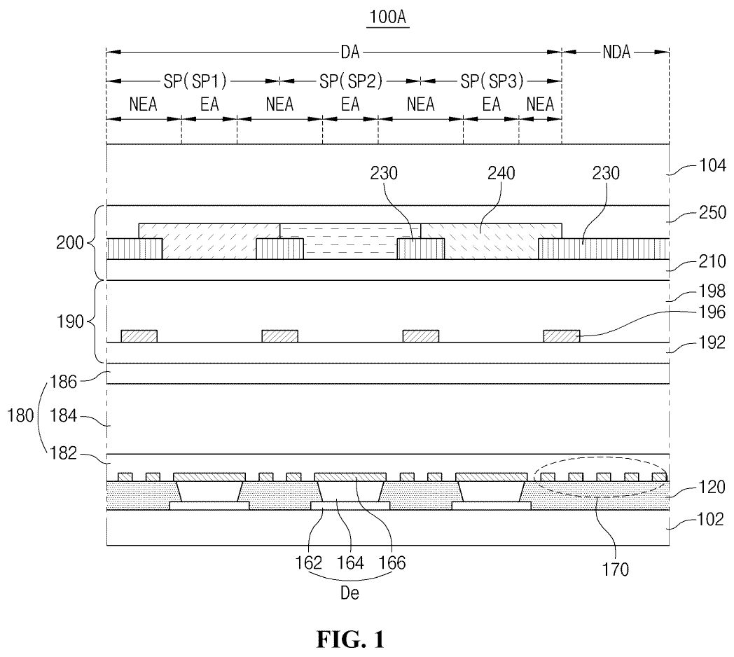

FIG. 1 is a schematic cross-sectional view of a display device according to a first embodiment of the present disclosure.

Referring to FIG. 1, the display device 100A according to the first embodiment of the present disclosure can include a display area DA implementing an image and a non-display area NDA provided on at least one side of the display area DA. A light-emitting diode De can be provided in the display area DA over a substrate 102. An encapsulation layer 180, a sensor unit 190, a color unit 200, and a cover window 104 can be provided over the light-emitting diode De.

Specifically, a plurality of sub-pixels SP can be provided in the display area DA. For example, the plurality of sub-pixels SP can include three sub-pixels constituting a pixel, that is, first, second, and third sub-pixels SP1, SP2, and SP3. The first, second, and third sub-pixels SP1, SP2, and SP3 can be red, green, and blue sub-pixels, respectively. However, embodiments of the present disclosure are not limited thereto. In other embodiments, the number of sub-pixels SP constituting one pixel can vary.

Each sub-pixel SP can include an emission area EA and a non-emission area NEA. The light-emitting diode De can be provided to correspond to the emission area EA over the substrate 102. The light-emitting diode De can include a first electrode 162, a light-emitting layer 164, and a second electrode 166.

A pixel defining layer 120 can be provided to correspond to the non-emission area NEA over the substrate 102. The pixel defining layer 120 can be disposed between the emission areas EA of adjacent sub-pixels SP. In addition, the pixel defining layer 120 can also be provided in the non-display area NDA. The pixel defining layer 120 can have a light-absorbing property. The pixel defining layer 120 can be a black bank.

A first light-blocking part 170 can be provided over the pixel defining layer 120. The first light-blocking part 170 can be disposed in the non-emission area NEA and the non-display area NDA. The first light-blocking part 170 can overlap the pixel defining layer 120.

The first light-blocking part 170 can selectively transmit light. That is, the first light-blocking part 170 can transmit light parallel to a transmission axis thereof and reflect light perpendicular to the transmission axis.

The first light-blocking part 170 can be formed of a metallic material. For example, the first light-blocking part 170 can be formed of aluminum (Al), but are not limited thereto.

The first light-blocking part 170 can be formed of the same material and on the same layer as the second electrode 166. In this case, the first light-blocking part 170 can be connected to the second electrode 166, and this will be described in detail later.

Next, the encapsulation layer 180 can be provided over the light-emitting diode De and the first light-blocking part 170. The encapsulation layer 180 can be disposed in the display area DA and the non-display area NDA. The encapsulation layer 180 can have a multiple-layered structure including at least one inorganic layer and at least one organic layer.

For example, the encapsulation layer 180 can include first, second, and third encapsulation layers 182, 184, and 186. In this case, the second encapsulation layer 184 can be disposed between the first and third encapsulation layers 182 and 186. The first and third encapsulation layers 182 and 186 can be an inorganic layer, and the second encapsulation layer 184 can be an organic layer.

The sensor unit 190 can be provided over the encapsulation layer 180 to detect an external input such as a touch. The sensor unit 190 can include a sensor buffer layer 192, a sensor electrode 196, and a sensor passivation layer 198.

The sensor buffer layer 192 can be provided over the encapsulation layer 180, the sensor electrode 196 can be provided over the sensor buffer layer 192, and the sensor passivation layer 198 can be provided over the sensor electrode 196. The sensor buffer layer 192 and the sensor passivation layer 198 can be disposed in the display area DA and the non-display area NDA. The sensor electrode 196 can be disposed in the display area DA.

The color unit 200 can be provided over the sensor unit 190. The color unit 200 can include a color buffer layer 210, a color filter layer 240, and a color protection layer 250. In addition, the color unit 200 can further include a second light-blocking part 230.

The color buffer layer 210 can be provided over the sensor unit 190, the color filter layer 240 and the second light-blocking part 230 can be provided over the color buffer layer 210, and the color protection layer 250 can be provided over the color filter layer 240. The color buffer layer 210 and the color protection layer 250 can be disposed in the display area DA and the non-display area NDA.

The color filter layer 240 can be provided to correspond to the emission area EA of each sub-pixel SP. The color filter layer 240 can include first, second, and third color filters corresponding to the first, second, and third sub-pixels SP1, SP2, and SP3, respectively. For example, the first, second, and third color filters can be red, green, and blue color filters, respectively.

The second light-blocking part 230 can be provided to correspond to the non-emission area NEA of the display area DA. The second light-blocking part 230 can overlap the color filter layer 240. In addition, the second light-blocking part 230 can also be provided in the non-display area NDA. The second light-blocking part 230 can overlap the pixel defining layer 120 and the first light-blocking part 170.

The second light-blocking part 230 can selectively transmit light. That is, the second light-blocking part 230 can transmit light parallel to a transmission axis thereof and reflect light perpendicular to the transmission axis.

Here, the transmission axis of the second light-blocking part 230 can coincide with the transmission axis of the first light-blocking part 170. That is, the transmission axis of the second light-blocking part 230 can have the same direction as and be parallel to the transmission axis of the first light-blocking part 170.

The second light-blocking part 230 can include a reactive mesogen (RM) as a host and a dichroic dye as a guest. The dichroic dye can be arranged in a predetermined direction by the reactive mesogen, thereby absorbing light parallel to the predetermined direction and transmitting light perpendicular to the predetermined direction.

The cover window 104 can be provided over the color unit 200. The cover window 104 can protect elements disposed thereunder from external impacts, moisture, oxygen, or particles. The cover window 104 can be formed of glass or a transparent film.

As such, in the display device 100A according to the first embodiment of the present disclosure, the color filter layer 240 can be provided over the light-emitting diode De in the emission area EA of the display area DA, thereby improving the reflection visibility and/or viewing angles.

Further, in the display device 100A according to the first embodiment of the present disclosure, by providing the pixel defining layer 120 absorbing light, the first light-blocking part 170, and the second light-blocking part 230 in the non-emission area NEA of the display area DA and the non-display area NDA, the external light can be prevented from being reflected and outputted to the outside. Accordingly, image quality can be improved by minimizing stains caused by reflection of the external light.

In addition, since the same configuration preventing the reflection of the external light is provided in the display area DA and the non-display area NDA, the reflectance and reflection visibility characteristics can be the same in the display area DA and the non-display area NDA, and thus a sense of unity can be implemented.

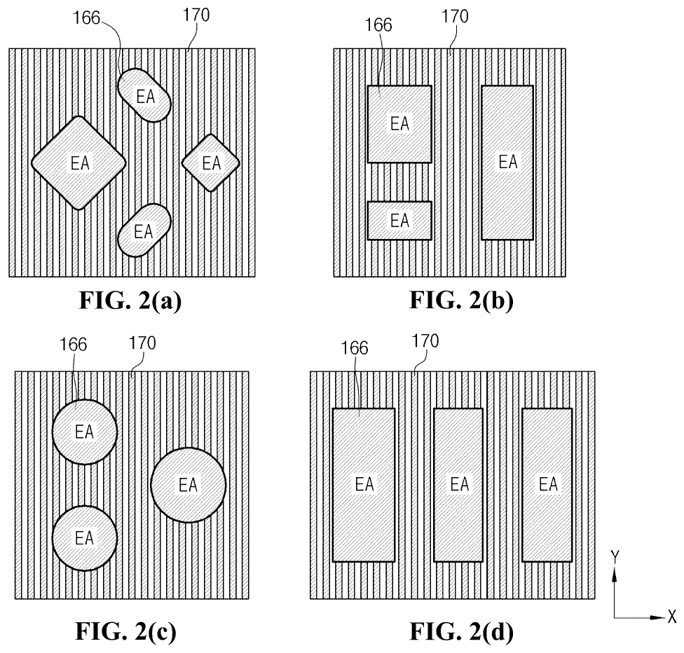

As described above, the first light-blocking part 170 of the display device 100A according to the first embodiment of the present disclosure can be formed of the same material and provided on the same layer as the second electrode 166 of the light-emitting diode De. This will be described with reference to FIG. 2(a) to 2(d).

FIG. 2(a) to 2(d) are schematic plan views of a display device according to the first embodiment of the present disclosure. FIG. 2(a) to 2(d) show various shapes and arrangements of the emission areas EA of the plurality of sub-pixels and the first light-blocking part 170 corresponding to one pixel.

Here, FIG. 2(a) shows the emission areas EA of four sub-pixels, and FIG. 2(b), 2(c), and 2(d) show the emission areas EA of three sub-pixels. The emission areas EA of the plurality of sub-pixels can have different shapes and/or areas. However, embodiments of the present disclosure are not limited thereto. In other embodiments, the emission areas EA of the plurality of sub-pixels can have the same shape and/or area.

As shown in FIG. 2(a), the emission areas EA of the four sub-pixels can have a substantially rectangular or oval shape and can be spaced apart in the first direction X and the second direction Y to form a cross shape.

As shown in FIG. 2(b) and FIG. 2(c), all of the emission areas EA of the three sub-pixels can have a rectangular shape or a circular shape. In this case, the emission areas EA of two sub-pixels can be spaced apart from each other in the second direction Y, and the emission area EA of the remaining one sub-pixel can be spaced apart from the emission areas EA of the two sub-pixels in the first direction X.

As shown in FIG. 2(d), all of the emission areas EA of the three sub-pixels can have a rectangular shape and can be spaced apart in the first direction X.

Referring to FIG. 2(a) to 2(d), the second electrode 166 can be provided in each emission area EA, and the first light-blocking part 170 can be provided between adjacent emission areas EA, i.e., in the non-emission area NEA.

The first light-blocking part 170 can include a plurality of patterns spaced apart from each other in the first direction X and extending in the second direction Y. The first light-blocking part 170 can selectively transmit light, and the transmission axis of the first light-blocking part 170 can be perpendicular to the extending direction of the patterns, that is, the second direction Y. Accordingly, the transmission axis of the first light-blocking part 170 can be parallel to the first direction X. However, embodiments of the present disclosure are not limited thereto. In other embodiments, the first light-blocking part 170 can include a plurality of patterns spaced apart from each other in the second direction Y and extending in the first direction X.

The first light-blocking part 170 can be formed of the same material and on the same layer as the second electrode 166. In this case, a portion of the first light-blocking part 170 can be connected to the second electrode 166 of the emission area EA and can be formed as one body.

Meanwhile, the second light-blocking part 230 of FIG. 1 can be disposed substantially identically to the first light-blocking part 170, that is, can be disposed in the non-emission area NEA between adjacent emission areas EA.

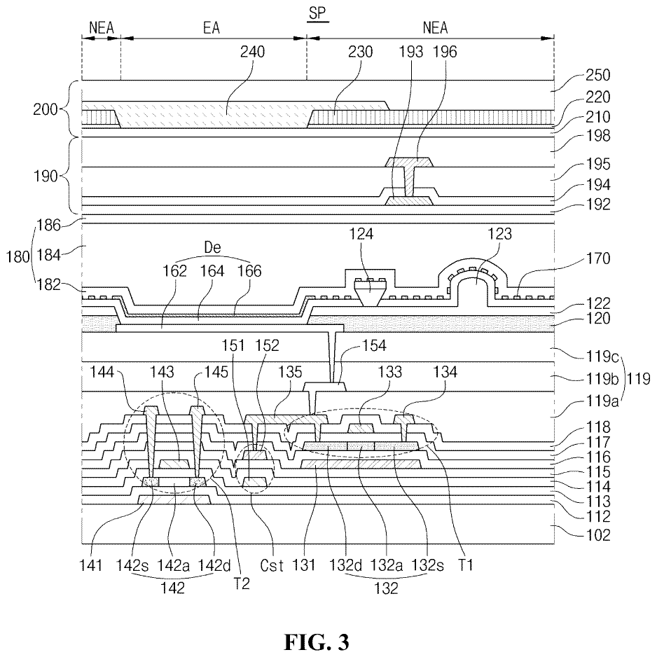

A configuration of the sub-pixel of the display device 100A according to the first embodiment of the present disclosure will be described in detail with reference to FIG. 3.

FIG. 3 is a schematic cross-sectional view of the display device according to the first embodiment of the present disclosure.

Referring to FIG. 3, the sub-pixel SP of the display device 100A according to the first embodiment of the present disclosure can include a first transistor T1, a second transistor T2, a storage capacitor Cst, the light-emitting diode De, the encapsulation layer 180, the sensor unit 190, and the color unit 200. In addition, a first light-shielding layer 131 can be provided under the first transistor T1, and a second light-shielding layer 141 can be provided under the second transistor T2.

The first transistor T1 can include a first active layer 132, a first gate electrode 133, a first source electrode 134, and a first drain electrode 135. The second transistor T2 can include a second active layer 142, a second gate electrode 143, a second source electrode 144, and a second drain electrode 145. The first active layer 132 and the second active layer 142 can be formed of different materials.

The first transistor T1 can be an oxide semiconductor thin film transistor, and the second transistor T2 can be a low temperature polycrystalline silicon thin film transistor.

Specifically, the substrate 102 can be a flexible substrate. The substrate 102 can have a multiple-layered structure and can include first, second, and third base layers, for example.

The first and third base layers can be formed of plastic with relatively high thermal stability. For example, the first and third base layers can be formed of polyimide, poly ether sulfone, poly ether ketone, polyamide, or poly benzimidazole, but are not limited thereto.

The second base layer can be inserted between the first and third base layers to increase stiffness of the substrate and improve the moisture-blocking properties. The second base layer can be an inorganic layer. For example, the second base layer can be formed of an inorganic insulating material such as silicon oxide (SiOx) or silicon nitride (SiNx). Alternatively, the second base layer can be formed of a metallic material such as copper (Cu), aluminum (Al), or stainless steel (SUS).

However, embodiments of the present disclosure are not limited thereto. In other embodiments, the substrate 102 can be a glass substrate and can have a single-layered structure.

The second light-shielding layer 141 can be provided over the substrate 102. The second light-shielding layer 141 can be formed of a conductive material such as metal. For example, the second light-shielding layer 141 can be formed of at least one of aluminum (Al), copper (Cu), molybdenum (Mo), titanium (Ti), chromium (Cr), nickel (Ni), tungsten (W), or an alloy thereof. The second light-shielding layer 141 can have a single-layered structure or a multiple-layered structure.

Although not shown in the figure, a buffer layer can be further provided between the substrate 102 and the second light-shielding layer 141. The buffer layer can be formed as a single layer or multiple layers of an inorganic insulating material.

A first buffer layer 112 of an inorganic insulating material can be provided over the second light-shielding layer 141. For example, the inorganic insulating material of the first buffer layer 112 can include silicon nitride (SiNx), silicon oxide (SiOx), or silicon oxynitride (SiON).

The second active layer 142 can be provided over the first buffer layer 112. The second active layer 142 can overlap the second light-shielding layer 141. The second light-shielding layer 141 can block light incident on the second active layer 142 and prevent or reduce the second active layer 142 from deteriorating due to the light.

The second active layer 142 can include a channel region 142a at its central portion and source and drain regions 142s and 142d at both sides of the channel region 142a. The second active layer 142 can be formed of a polycrystalline semiconductor material, i.e., polycrystalline silicon, and the source and drain regions 142s and 142d of the second active layer 142 can be doped with impurities.

A first gate insulation layer 113 can be provided over the second active layer 142. The first gate insulation layer 113 can be formed as a single layer or multiple layers of an inorganic insulating material. For example, the inorganic insulating material of the first gate insulation layer 113 can include silicon nitride (SiNx), silicon oxide (SiOx), or silicon oxynitride (SiON).

The second gate electrode 143 can be provided over the first gate insulation layer 113. The second gate electrode 143 can be formed of a conductive material such as metal. For example, the second gate electrode 143 can be formed of at least one of aluminum (Al), copper (Cu), molybdenum (Mo), titanium (Ti), chromium (Cr), nickel (Ni), tungsten (W), or an alloy thereof. The second gate electrode 143 can have a single-layered structure or a multiple-layered structure.

The second gate electrode 143 can be disposed to correspond to the central portion of the second active layer 142 and can overlap the channel region 142a of the second active layer 142.

In addition, a first capacitor electrode 151 can be provided over the first gate insulation layer 113. The first capacitor electrode 151 can be formed of the same material and on the same layer as the second gate electrode 143.

A first interlayer insulation layer 114 can be provided over the second gate electrode 143 and the first capacitor electrode 151. The first interlayer insulation layer 114 can be formed as a single layer or multiple layers of an inorganic insulating material. For example, the inorganic insulating material of the first interlayer insulation layer 114 can include silicon nitride (SiNx), silicon oxide (SiOx), or silicon oxynitride (SiON).

A second buffer layer 115 can be provided over the first interlayer insulation layer 114. The second buffer layer 115 can be formed as a single layer or multiple layers of an inorganic insulating material. For example, the inorganic insulating material of the second buffer layer 115 can include silicon nitride (SiNx), silicon oxide (SiOx), or silicon oxynitride (SiON).

The first light-shielding layer 131 can be provided over the second buffer layer 115. The first light-shielding layer 131 can be spaced apart from the second light-shielding layer 141, the first capacitor electrode 151, and the second transistor T2. The first light-shielding layer 131 can be formed of a conductive material such as metal. For example, the first light-shielding layer 131 can be formed of at least one of aluminum (Al), copper (Cu), molybdenum (Mo), titanium (Ti), chromium (Cr), nickel (Ni), tungsten (W), or an alloy thereof. The first light-shielding layer 131 can have a single-layered structure or a multiple-layered structure.

In addition, a second capacitor electrode 152 can be provided over the second buffer layer 115. The second capacitor electrode 152 can be formed of the same material and on the same layer as the first light-shielding layer 131. The second capacitor electrode 152 can overlap the first capacitor electrode 151 to form the storage capacitor Cst.

A third buffer layer 116 can be provided over the first light-shielding layer 131 and the second capacitor electrode 152. The third buffer layer 116 can be formed as a single layer or multiple layers of an inorganic insulating material. For example, the inorganic insulating material of the third buffer layer 116 can include silicon nitride (SiNx), silicon oxide (SiOx), or silicon oxynitride (SiON).

The first active layer 132 can be provided over the third buffer layer 116. The first active layer 132 can overlap the first light-shielding layer 131. The first light-shielding layer 131 can block light incident on the first active layer 132 and prevent or reduce the first active layer 132 from deteriorating due to the light.

The first active layer 132 can include a channel region 132a at its central portion and source and drain regions 132s and 132d at both sides of the channel region 132a. For example, the first active layer 132 can be formed of an oxide semiconductor material, such as indium gallium zinc oxide (IGZO), zinc oxide (ZnO), tin oxide (SnO₂), copper oxide (Cu₂°), nickel oxide (NiO), indium tin zinc oxide (ITZO), indium aluminum zinc oxide (IAZO).

The source and drain regions 132s and 132d of the first active layer 132 can be doped with impurities. However, embodiments of the present disclosure are not limited thereto. In other embodiments, the source and drain regions 132s and 132d of the first active layer 132 may not be doped with impurities.

A second gate insulation layer 117 can be provided over the first active layer 132. The second gate insulation layer 117 can be formed as a single layer or multiple layers of an inorganic insulating material. For example, the inorganic insulating material of the second gate insulation layer 117 can include silicon nitride (SiNx), silicon oxide (SiOx), or silicon oxynitride (SiON).

The first gate electrode 133 can be provided over the second gate insulation layer 117. The first gate electrode 133 can be formed of a conductive material such as metal. For example, the first gate electrode 133 can be formed of at least one of aluminum (Al), copper (Cu), molybdenum (Mo), titanium (Ti), chromium (Cr), nickel (Ni), tungsten (W), or an alloy thereof. The first gate electrode 133 can have a single-layered structure or a multiple-layered structure.

The first gate electrode 133 can be disposed to correspond to the central portion of the first active layer 132 and can overlap the channel region 132a of the first active layer 132.

A second interlayer insulation layer 118 can be provided over the first gate electrode 133. The second interlayer insulation layer 118 can be formed as a single layer or multiple layers of an inorganic insulating material. For example, the inorganic insulating material of the second interlayer insulation layer 118 can include silicon nitride (SiNx), silicon oxide (SiOx), or silicon oxynitride (SiON).

The first source and first drain electrodes 134 and 135 and the second source and second drain electrodes 144 and 145 can be provided over the second interlayer insulation layer 118. The first gate electrode 133 can be provided over the second gate insulation layer 117. The first source and first drain electrodes 134 and 135 and the second source and second drain electrodes 144 and 145 can be formed of a conductive material such as metal. For example, the first source and first drain electrodes 134 and 135 and the second source and second drain electrodes 144 and 145 can be formed of at least one of aluminum (Al), copper (Cu), molybdenum (Mo), titanium (Ti), chromium (Cr), nickel (Ni), tungsten (W), or an alloy thereof. The first source and first drain electrodes 134 and 135 and the second source and second drain electrodes 144 and 145 can have a single-layered structure or a multiple-layered structure.

The first source and first drain electrodes 134 and 135 can be spaced apart from each other with the first gate electrode 133 positioned therebetween and can be in contact with the source and drain regions 132s and 132d of the first active layer 132 through contact holes provided in the second gate insulation layer 117 and the second interlayer insulation layer 118, respectively.

In addition, the first drain electrode 135 can extend to overlap the first and second capacitor electrodes 151 and 152. The first drain electrode 135 can be in contact with the second capacitor electrode 152 through a contact hole provided in the third buffer layer 116, the second gate insulation layer 117, and the second interlayer insulation layer 118 and can be electrically connected to the second capacitor electrode 152.

Meanwhile, the second source and second drain electrodes 144 and 145 can be spaced apart from each other with the second gate electrode 143 positioned therebetween and can be in contact with the source and drain regions 142s and 142d of the second active layer 142 through contact holes provided in the first gate insulation layer 113, the first interlayer insulation layer 114, the second buffer layer 115, the third buffer layer 116, the second gate insulation layer 117, and the second interlayer insulation layer 118, respectively.

The first active layer 132, the first gate electrode 133, the first source electrode 134, and the first drain electrode 135 can constitute a first transistor T1. The second active layer 142, the second gate electrode 143, the second source electrode 144, and the second drain electrode 145 can constitute a second transistor T2. The first transistor T1 can be a driving transistor and/or an emission transistor. The second transistor T2 can be a switching transistor and/or a sensing transistor and can be electrically connected to the first transistor T1.

The second drain electrode 145 of the second transistor T2 can be connected to the first gate electrode 133 of the first transistor T1. Here, the second transistor T2 can be switched according to a scan signal transmitted through a gate line and can transmit a data signal, which is inputted to the second source electrode 144 through a data line, to the first gate electrode 133 through the second drain electrode 145. In addition, the first transistor T1 can be switched according to the data signal and can transmit a power voltage, which is inputted to the first source electrode 134, to the light-emitting diode De through the first drain electrode 135.

As such, the display device 100A according to the first embodiment of the present disclosure can include the first transistor T1 and the second transistor T2 having different configurations. Here, the first transistor T1 can be an oxide semiconductor thin film transistor using an oxide semiconductor material as the first active layer 132. The oxide semiconductor thin film transistor can have an excellent effect of blocking leakage currents and can be manufactured at relatively low costs. On the other hand, the second transistor T2 can be a low temperature polycrystalline silicon thin film transistor using a polycrystalline semiconductor material as the second active layer 142. The low temperature polycrystalline silicon thin film transistor can have fast operation speeds and excellent reliability.

Accordingly, the display device 100A according to the first embodiment of the present disclosure can include both the oxide semiconductor thin film transistor and the low temperature polycrystalline silicon thin film transistor and can selectively apply them according to operation properties, thereby improving the driving characteristics of the display device.

One or more switching transistors having the same configuration as the first transistor T1 and/or the second transistor T2 can be further provided over the substrate 102. However, embodiments of the present disclosure are not limited thereto. In other embodiments, the driving transistor and/or emission transistor can have the same configuration as the second transistor T2, and the switching and/or sensing transistor can have the same configuration as the first transistor T1.

Alternatively, the second transistor T2 can be a transistor of a gate driving unit provided over the substrate 102, and the gate driving unit can further include a transistor having the same configuration as the first transistor T1.

Next, a planarization layer 119 can be provided over the first source and first drain electrodes 134 and 135 and the second source and second drain electrodes 144 and 145. Although not shown in the figure, an inorganic layer of an inorganic insulating material can be further provided under the planarization layer 119.

The planarization layer 119 can eliminate a step difference due to the layers thereunder and can have a substantially flat top surface. The planarization layer 119 can be formed of an organic insulating material such as photosensitive acrylic polymer (photo acryl) or benzocyclobutene (BCB).

The planarization layer 119 can have a multiple-layered structure. For example, the planarization layer 119 can include first, second, and third planarization layers 119a, 119b, and 119c.

Specifically, the first planarization layer 119a can be provided over the first source and first drain electrodes 134 and 135 and the second source and second drain electrodes 144 and 145.

A connection electrode 154 can be provided over the first planarization layer 119a. The connection electrode 154 can overlap the first drain electrode 135 and can be in contact with the first drain electrode 135 through a contact hole provided in the first planarization layer 119a.

The connection electrode 154 can be formed of a conductive material such as metal. For example, the connection electrode 154 can be formed of at least one of aluminum (Al), copper (Cu), molybdenum (Mo), titanium (Ti), chromium (Cr), nickel (Ni), tungsten (W), or an alloy thereof. The connection electrode 154 can have a single-layered structure or a multiple-layered structure.

The second planarization layer 119b can be provided over the connection electrode 154, and the third planarization layer 119c can be provided over the second planarization layer 119b.

In a display device including the light-emitting diode De, there can be a problem such as a decrease in a lifetime of the light-emitting diode De because flatness of the first electrode 162 of the light-emitting diode De decreases due to a step difference caused by electrodes or lines provided under the light-emitting diode De. However, in the display device 100A according to the first embodiment of the present disclosure, since the planarization layer 119 having the multiple-layered structure is provided under the light-emitting diode De, the problem due to the step difference can be prevented.

Here, the planarization layer 119 has been described as having a triple-layered structure including the first, second, and third planarization layers 119a, 119b, and 119c. However, embodiments of the present disclosure are not limited thereto. In other embodiments, the connection electrode 154 and the first planarization layer 119a can be omitted, and the planarization layer 119 can have a double-layered structure. Additionally, in other embodiments, an additional planarization layer can be further provided, and the planarization layer 119 can have a multiple-layered structure including four layers or more.

Next, the first electrode 162 can be provided over the third planarization layer 119c and can be formed of a conductive material having relatively high work function. The first electrode 162 can be in contact with the connection electrode 154 through a contact hole provided in the second and third planarization layers 119b and 119c. Accordingly, the first electrode 162 can be electrically connected to the first drain electrode 135 of the first transistor T1 through the connection electrode 154.

Alternatively, when the connection electrode 154 and the first planarization layer 119a are omitted, the first electrode 162 can be in direct contact with the first drain electrode 135 through the contact hole provided in the second and third planarization layers 119b and 119c.

For example, the first electrode 162 can include a transparent conductive material such as indium tin oxide (ITO) or indium zinc oxide (IZO) or include titanium (Ti). However, embodiments of the present disclosure are not limited thereto.

Meanwhile, the first electrode 162 can have a multi-layered structure including a material with relatively high reflectance. For example, the first electrode 162 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

The pixel defining layer 120 of an organic insulating material can be provided on the first electrode 162. The pixel defining layer 120 can overlap edges of the first electrode 162 and cover the edges of the first electrode 162. The pixel defining layer 120 can expose a central portion of the first electrode 162. The pixel defining layer 120 can cover the contact hole provided in the second and third planarization layer 119b and 119c.

The pixel defining layer 120 can have an opening exposing the central portion of the first electrode 162. The pixel defining layer 120 can be disposed to correspond to the non-emission area NEA, and the opening of the pixel defining layer 120 can correspond to the emission area EA.

The pixel defining layer 120 can have a light-absorbing property. The pixel defining layer 120 can be a black bank. The pixel defining layer 120 can include black particles (light-absorbing particles) dispersed in an organic material (binder). For example, the organic material can be one of photosensitive acrylic polymer (photo acryl), benzocyclobutene (BCB), and polyimide, and the light-absorbing particles can be one of carbon black, carbon nanotubes (CNTs), and graphene.

A first spacer 123 having a substantially positive taper shape and a second spacer 124 having a reverse taper shape can be provided over the pixel defining layer 120.

The first spacer 123 can support a metal mask used when forming the light-emitting layer 164 later, and the second spacer 124 can separate the light-emitting layer 164 and the second electrode 166 to be formed later to block lateral leakage current between adjacent sub-pixels SP.

The first and second spacers 123 and 124 can be formed as a single layer or multiple layers of an organic insulating material such as photosensitive acrylic polymer (photo acryl) or benzocyclobutene (BCB). At least one of the first and second spacers 123 and 124 can be omitted.

Meanwhile, an auxiliary define layer 122 can be provided between the pixel defining layer 120 and the first and second spacers 123 and 124. The auxiliary define layer 122 can have substantially the same shape as the pixel defining layer 120. That is, the auxiliary define layer 122 can have an opening exposing the central portion of the first electrode 162 and can be disposed to correspond to the non-emission area NEA.

The auxiliary define layer 122 can be formed of the same material as the first and second spacers 123 and 124. In this case, the auxiliary define layer 122 can be connected to the first spacer 123 and formed as one body with the first spacer 123.

Here, the auxiliary define layer 122 can have a different property from the pixel defining layer 120, namely, a light-transmitting property. The auxiliary define layer 122 can be formed of the same organic material as the binder of the pixel defining layer 120 and may not include light-absorbing particles.

The auxiliary define layer 122 can be formed to facilitate patterning of the pixel defining layer 120 having the light-absorbing property and can be omitted. Accordingly, the first and second spacers 123 and 124 can be formed directly on the pixel defining layer 120.

The light-emitting layer 164 can be provided over the first electrode 162 exposed through the openings of the pixel defining layer 120 and the auxiliary define layer 122. The light-emitting layer 164 can also be provided over the auxiliary define layer 122 and the first and second spacers 123 and 124.

The light-emitting layer 164 can include at least one hole auxiliary layer, at least one light-emitting material layer, and at least one electron auxiliary layer constituting one light-emitting unit.

The light-emitting material layer can include one of red, green, and blue luminescent materials. The luminescent material can be an organic luminescent material such as a phosphorescent compound or a fluorescent compound or can be an inorganic luminescent material such as a quantum dot.

The hole auxiliary layer can include at least one of a hole injection layer (HIL) and a hole transport layer (HTL). The electron auxiliary layer can include at least one of an electron injection layer (EIL) and an electron transport layer (ETL).

The light-emitting layer 164 can emit white light and can be disposed substantially all over the display area DA. In this case, the light-emitting layer 164 can include a plurality of light-emitting units emitting light of different colors and being stacked. Each stack can include at least one hole auxiliary layer, at least one light-emitting material layer, and at least one electron auxiliary layer.

For example, the light-emitting layer 164 can have a stack structure in which two or more light-emitting units emitting different colors are stacked, and a charge generation layer (CGL) can be provided between two or more light-emitting units.

However, embodiments of the present disclosure are not limited thereto. In other embodiments, the light-emitting layer 164 can be separately provided for each sub-pixel and can emit one of red, green, and blue lights.

The light-emitting layer 164 can be separated by the second spacer 124. That is, a portion of the light-emitting layer 164 over the auxiliary define layer 122 can be separated from a portion of the light-emitting layer 164 over the second spacer 124 without being connected.

The second electrode 166 can be provided over the light-emitting layer 164 and can be formed of a conductive material with relatively low work function. The second electrode 166 can be disposed in the emission area EA.

The second electrode 166 can be formed of aluminum (Al), magnesium (Mg), silver (Ag), or an alloy thereof. In this case, the second electrode 166 can have a relatively thin thickness such that light from the light-emitting layer 164 can be transmitted therethrough. For example, the second electrode 166 can have a thickness of 5 nm to 10 nm, but embodiments of the present disclosure are not limited thereto.

Alternatively, the second electrode 166 can be formed of a transparent conductive material such as indium gallium oxide (IGO) or IZO.

The first electrode 162, the light-emitting layer 164, and the second electrode 166 can constitute the light-emitting diode De. Here, the first electrode 162 can serve as an anode, and the second electrode 166 can serve as a cathode. However, embodiments of the present disclosure are not limited thereto. In other embodiments, the first electrode 162 can serve as a cathode, and the second electrode 166 can serve as an anode.

Light emitted from the light-emitting layer 164 of the light-emitting diode De can be outputted to the outside through the second electrode 166. Such a display device 100A according to the first embodiment of the present disclosure can be a top-emission type display device.

Meanwhile, the first light-blocking part 170 can be provided over the light-emitting layer 164 in the non-emission area NEA. The first light-blocking part 170 can overlap the pixel defining layer 120, the auxiliary define layer 122, and the first and second spacers 123 and 124.

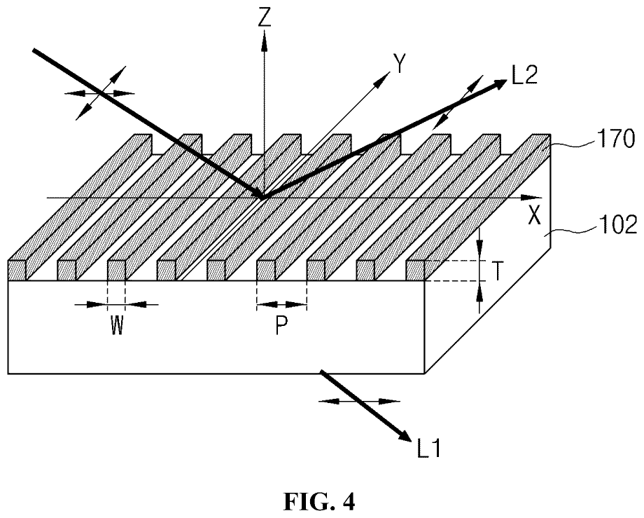

The first light-blocking part 170 will be described in detail with reference to FIG. 4. FIG. 4 is a schematic perspective view of the first light-blocking part according to an embodiment of the present disclosure and shows only the substrate and the first light-blocking part for convenience of illustration.

Referring to FIG. 4, the first light-blocking part 170 can be a wire grid polarizer that selectively reflects or transmits light by exciting metal electrons on the grid in one direction, thereby creating a single polarization.

Specifically, the first light-blocking part 170 can include a plurality of wire grids spaced apart from each other in the first direction X and extending in the second direction Y over the substrate 102. The first light-blocking part 170 can transmit linearly polarized light L1 of the first direction X vibrating perpendicular to the wire grids and reflect linearly polarized light L2 of the second direction Y vibrating parallel to the wire grids.

However, the direction of the wire grids is not limited thereto. In other embodiments, the wire grids can be spaced apart from each other in the second direction Y and extending in the first direction X. In this case, the first light-blocking part 170 can reflect the linearly polarized light L1 of the first direction X vibrating perpendicular to the wire grids and transmit the linearly polarized light L2 of the second direction Y vibrating parallel to the wire grids. Alternatively, in other embodiments, the wire grids can extend in a third direction crossing the first and second directions X and Y and can be spaced apart from each other in a fourth direction perpendicular to the third direction.

To ensure polarization equivalent to that of a related art polarizing plate, a pitch P of the wire grids, preferably, can be less than or equal to λ/2. Considering the visible light wavelength range of 380 nm to 780 nm, the pitch P of the wire grids can be 200 nm or less, and preferably, 150 nm to 170 nm.

In this case, a width W of the wire grids, preferably, can be equal to or less than ½ of the pitch P. For example, the width W can be 0.45 to 0.5 times of the pitch P. In addition, a thickness T of the wire grids, preferably, can be 50 nm or less.

As described above, the first light-blocking part 170 can be formed of the same material and on the same layer as the second electrode 166. At this time, the thickness T of the wire grids can be equal to a thickness of the second electrode 166, and for example, 5 nm to 10 nm.

The first light-blocking part 170 and the second electrode 166 can be formed by depositing a metal material over the substrate 102 to form a metal layer and selectively removing the metal layer in the non-emission area NEA through a photolithography process. In this case, a portion of the first light-blocking part 170 can be connected to the second electrode 166 and be formed as one body with the second electrode 166.

Referring to FIG. 3 again, the encapsulation layer 180 can be provided over the second electrode 166 and the first light-blocking part 170. The encapsulation layer 180 can protect the light-emitting diode De from external moisture or oxygen.

The encapsulation layer 180 can have a stacked structure of the first, second, and third encapsulation layers 182, 184, and 186, and the second encapsulation layer 184 can be disposed between the first encapsulation layer 182 and the third encapsulation layer 186. The first and third encapsulation layers 182 and 186 can be formed of an inorganic insulating material, and the second encapsulation layer 184 can be formed of an organic insulating material. Here, the second encapsulation layer 184 can be a layer covering particles generated during a manufacturing process.

For example, the first and third encapsulation layers 182 and 186 can be formed of an inorganic insulating material such as silicon oxide (SiOx) or silicon nitride (SiNx), and the second encapsulation layer 184 can be formed of an organic insulating material such as an acrylic resin, epoxy resin, phenolic resin, polyamide resin, or polyimide resin.

Meanwhile, although not shown in the figure, a capping layer can be further provided between the second electrode 166 and the encapsulation layer 180. The capping layer can be formed of an insulating material having a relatively high refractive index. The wavelength of light traveling along the capping layer can be amplified by surface plasma resonance. Thus, the intensity of the peak can be increased, thereby improving the light efficiency in the display device. For example, the capping layer can be formed as a single layer of an organic layer or an inorganic layer, or can be formed as organic/inorganic stacked layers.

Next, the sensor unit 190 can be provided over the encapsulation layer 180 to detect an external input such as a touch. The sensor unit 190 can include a first sensor insulation layer 192, a bridge electrode 193, a second sensor insulation layer 194, a third sensor insulation layer 195, the sensor electrode 196, and a fourth sensor insulation layer 198.

Specifically, the first sensor insulation layer 192, which is the sensor buffer layer, can be provided over the encapsulation layer 180. The first sensor insulation layer 192 can be formed as a single layer or multiple layers of an inorganic insulating material. For example, the inorganic insulating material of the first sensor insulation layer 192 can include silicon nitride (SiNx), silicon oxide (SiOx), or silicon oxynitride (SiON).

The bridge electrode 193 of a conductive material can be provided over the first sensor insulation layer 192. The bridge electrode 193 can be disposed in the non-emission area NEA. The bridge electrode 193 can overlap the pixel defining layer 120 and can be spaced apart from the light-emitting diode De.

The second sensor insulation layer 194, which is an auxiliary sensor buffer layer, and the third sensor insulation layer 195, which is a sensor interlayer insulation layer, can be provided over the bridge electrode 193. The second sensor insulation layer 194 can be formed of an inorganic insulating material such as silicon nitride (SiNx), silicon oxide (SiOx), or silicon oxynitride (SiON), and the third sensor insulation layer 195 can be formed of an organic insulating material such as photosensitive acrylic polymer (photo acryl).

The sensor electrode 196 can be provided over the third sensor insulation layer 195 and be formed of a conductive material. The sensor electrode 196 can include a plurality of patterns, and the plurality of patterns can be selectively in contact with the bridge electrode 193 through contact holes provided in the second and third sensor insulation layers 194 and 195.

Accordingly, the plurality of patterns of the sensor electrode 196 can be selectively connected in the first direction X and/or the second direction Y through the bridge electrode 193 to form a first sensing line extending substantially in the first direction X and a second sensing line extending substantially in the second direction Y.

The fourth sensor insulation layer 198, which is the sensor passivation layer, can be provided over the sensor electrode 196. The fourth sensor insulation layer 198 can be formed of an organic insulating material such as photosensitive acrylic polymer (photo acryl).

As such, in the display device 100A according to the first embodiment of the present disclosure, the sensor unit 190 can be provided over the light-emitting diode De, thereby detecting the touch input of the user and performing a corresponding operation.

The color unit 200 can be provided over the sensor unit 190. The color unit 200 can include the color buffer layer 210, the color filter layer 240, and the color protection layer 250. In addition, the color unit 200 can further include an alignment layer 220 and the second light-blocking part 230.

Specifically, the color buffer layer 210 can be provided over the fourth sensor insulation layer 198 of the sensor unit 190. The color buffer layer 210 can be formed as a single layer or multiple layers of an inorganic insulating material. For example, the inorganic insulating material of the color buffer layer 210 can include silicon nitride (SiNx), silicon oxide (SiOx), or silicon oxynitride (SiON).

The second light-blocking part 230 can be provided in the non-emission area NEA over the color buffer layer 210. The second light-blocking part 230 can arrange dichroic dyes with an absorption spectrum in the visible light range using the reactive mesogen aligned in a specific direction to thereby achieve polarization.

The second light-blocking part 230 can have an opening corresponding to the emission area EA. The opening of the second light-blocking part 230 can have substantially the same size as the opening of the pixel defining layer 120. That is, the second light-blocking part 230 and the pixel defining layer 120 can have the same area. However, embodiments of the present disclosure are not limited thereto. In other embodiments, the opening of the second light-blocking part 230 can have a different size from the opening of the pixel defining layer 120. For example, in order to increase the viewing angles, the opening of the second light-blocking part 230 can be larger than the opening of the pixel defining layer 120.

In this case, the higher the alignment degree is, the higher the polarization is. To improve the alignment degree, the alignment layer 220 can have substantially the same shape and area as the second light-blocking part 230.

The alignment layer 220 can be formed by applying an organic insulating material such as polyimide over the color buffer layer 210 and aligning its surface in a predetermined direction through a photo-alignment method using ultraviolet (UV) light. Here, the UV light can only be irradiated to the non-emission area NEA.

Then, a mixture of the reactive mesogen and the dichroic dye can be formed over the alignment layer 220, and the UV light can be irradiated to the non-emission area NEA to strip and remove the alignment layer 220 and the mixture in the emission area EA that are not exposed to the UV light. Accordingly, the alignment layer 220 and the second light-blocking part 230 can be formed in the non-emission area NEA.

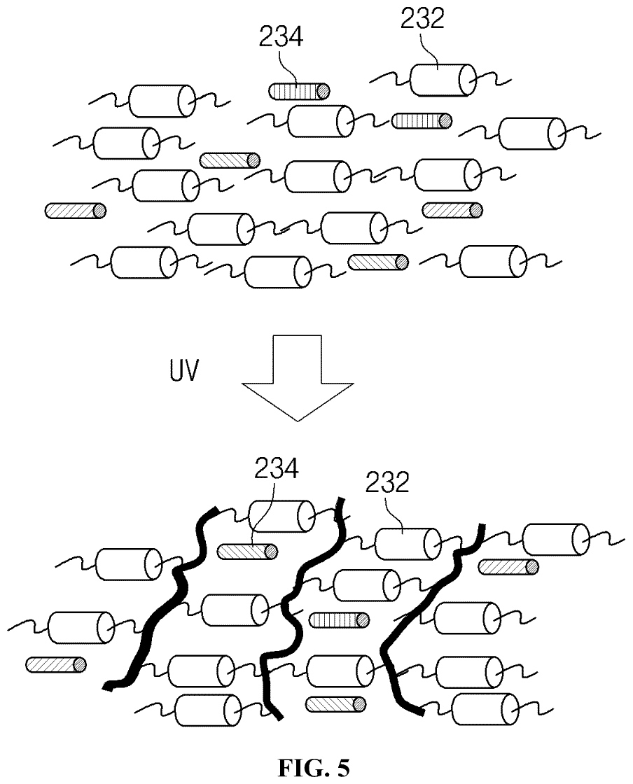

The configuration of the second light-blocking part 230 will be described in more detail with reference to FIG. 5. FIG. 5 is a schematic view illustrating the configuration of the second light-blocking part according to an embodiment of the present disclosure and shows an arrangement structure of the reactive mesogen and the dichroic dye before and after polymerization.

Referring to FIG. 5, the second light-blocking part 230 according to the embodiment of the present disclosure can include a reactive mesogen 232 and a dichroic dye 234.

The reactive mesogen 232 is a monomer molecule that includes a mesogen exhibiting liquid crystal properties and a polymerizable terminal functional group and has a liquid crystal phase. The reactive mesogen 232 can be used as an alignment host.

The reactive mesogen 232 can have a smectic phase with a relatively high degree of alignment. However, embodiments of the present disclosure are not limited thereto. In other embodiments, the reactive mesogen 232 can have a nematic phase.

The reactive mesogen 232 can be synthesized and then mixed with the dichroic dye 234 with liquid crystal properties. The dichroic dye 234 can include a plurality of dichroic dyes absorbing light of different wavelengths. For example, the dichroic dye 234 can include two or more of yellow, cyan, and magenta dichroic dyes. However, embodiments of the present disclosure are not limited thereto.

Next, when the reactive mesogen 232 is polymerized and cured by irradiating with UV light, the dichroic dye 234 can be aligned in the same direction as the alignment direction of the reactive mesogen 232 due to the liquid crystal properties thereof.

Accordingly, the dichroic dye 234 can absorb light parallel to the alignment direction and transmit light perpendicular to the alignment direction. The absorption axis of the second light-blocking part 230 can be parallel to the alignment direction of the dichroic dye 234, and the transmission axis of the second light-blocking part 230 can be perpendicular to the alignment direction of the dichroic dye 234.

Referring to FIG. 3 again, the color filter layer 240 can be provided in the emission area EA over the color buffer layer 210. The color filter layer 240 can also be partially disposed in the non-emission area NEA and can overlap and cover a portion of the second light-blocking part 230.

The color protection layer 250 can be provided over the second light-blocking part 230 and the color filter layer 240. The color protection layer 250 can cover and protect the color filter layer 240 and the second light-blocking part 230. The color protection layer 250 can be formed of an organic insulating material such as photosensitive acrylic polymer (photo acryl).

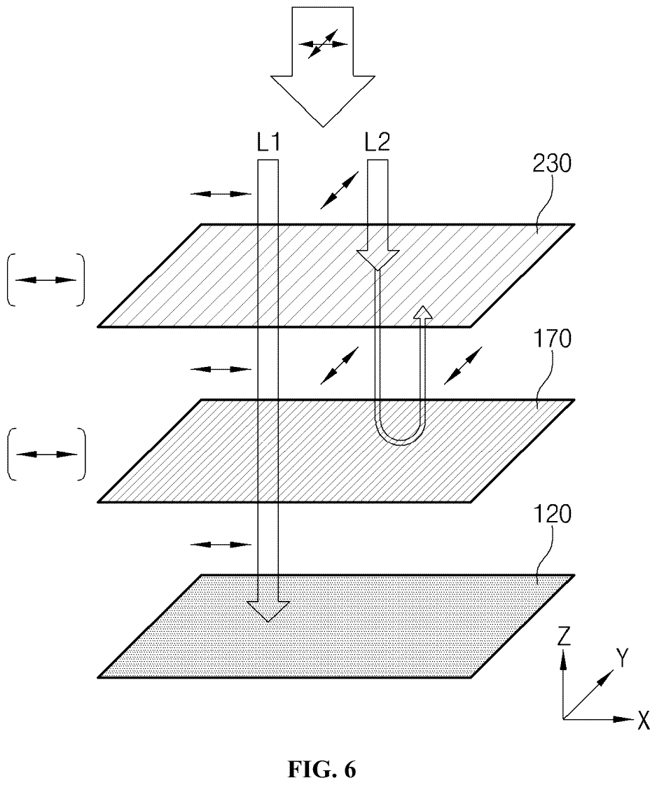

The configuration for preventing the reflection of the external light in the non-emission area NEA and the non-display area NDA of the display device 100A according to the first embodiment of the present disclosure will be described in detail with reference to FIG. 6.

FIG. 6 is a schematic view showing a path of the external light of the display device according to the first embodiment of the present disclosure and shows only the configurations that affect the path.

Referring to FIG. 6, the first light-blocking part 170 can be provided over the pixel defining layer 120, and the second light-blocking part 230 can be provided over the first light-blocking part 170.

The pixel defining layer 120 can have the light-absorbing property. The first light-blocking part 170 can selectively reflect or transmit light. The second light-blocking part 230 can selectively absorb or transmit light. Here, the transmission axes of the first light-blocking part 170 and the second light-blocking part 230 can coincide with each other and can be parallel to the first direction X.

However, embodiments of the present disclosure are not limited thereto. In other embodiments, the transmission axes of the first light-blocking part 170 and the second light-blocking part 230 can be parallel to the second direction Y. For example, when the first direction X is defined as 0 degrees and the second direction Y is defined as 90 degrees, the transmission axes of the first light-blocking part 170 and the second light-blocking part 230 can both be parallel to 0 degrees, or the transmission axes of the first light-blocking part 170 and the second light-blocking part 230 can both be parallel to 90 degrees. The transmission axes of the first light-blocking part 170 and the second light-blocking part 230 can be parallel to the gate line or the data line.

Alternatively, in other embodiments, the transmission axes of the first light-blocking part 170 and the second light-blocking part 230 can be parallel to 45 degrees or 135 degrees. In this case, the transmission axes of the first light-blocking part 170 and the second light-blocking part 230 can have an angle of 45 degrees with respect to the gate line or the data line.

Among unpolarized external light, the linearly polarized light L1 of the first direction X can coincide with the transmission axis direction of the second light-blocking part 230 and thus pass through the second light-blocking part 230. Then, since the linearly polarized light L1 coincides with the transmission axis direction of the first light-blocking part 170, the linearly polarized light L1 can pass through the first light-blocking part 170 and be absorbed by the pixel defining layer 120.

On the other hand, among the unpolarized external light, since the linearly polarized light L2 of the second direction Y coincides with the absorption axis direction of the second light-blocking part 230, the linearly polarized light L2 can be absorbed by the second light-blocking part 230. At this time, some of the linearly polarized light L2 may not be completely absorbed by the second light-blocking part 230 to thereby reach the first light-blocking part 170. Since some of the linearly polarized light L2 coincide with the reflection axis direction of the first light-blocking part 170, some of the linearly polarized light L2 can be reflected by the first light-blocking part 170 to thereby reach the second light-blocking part 230 again. Then, some of the linearly polarized light L2 reflected by the first light-blocking part 170 can coincide with the absorption axis direction of the second light-blocking part 230 and can be absorbed by the second light-blocking part 230.

Accordingly, the display device 100A according to the first embodiment of the present disclosure can include the first and second light-blocking parts 170 and 230 over the pixel defining layer 120 having the light-absorbing property to prevent the external light from being reflected and output, thereby preventing or minimizing a decrease in the display quality and/or leakage current problems of the thin film transistor due to the reflection of the external light.

In the display device 100A according to the first embodiment of the present disclosure, if the positions of the first light-blocking part 170 and the second light-blocking part 230 are changed, that is, if the second light-blocking part 230 is disposed between the pixel defining layer 120 and the first light-blocking part 170, the second light-blocking part 230 can be damaged by a subsequent process. In addition, among the unpolarized external light, the linearly polarized light L2 of the second direction Y can be reflected by the first light-blocking part 170, and thus the reflection of the external light cannot be blocked.

Alternatively, if the first light-blocking part 170 is configured identically to the second light-blocking part 230, that is, if the first light-blocking part 170 is configured to include the reactive mesogen 232 and the dichroic dye 234, the first light-blocking part 170 can be damaged during a subsequent process, resulting in a deterioration in the properties blocking the reflection of the external light and an increase in the processes and costs.

Otherwise, if the first light-blocking part 170 is omitted, some of the light passing through the second light-blocking part 230 can be reflected by the second electrode 166 over the pixel defining layer 120 and then output to the outside, and other of the light can pass through the second electrode 166 and be absorbed by the pixel defining layer 120, which may cause a problem of the reflection of the external light.

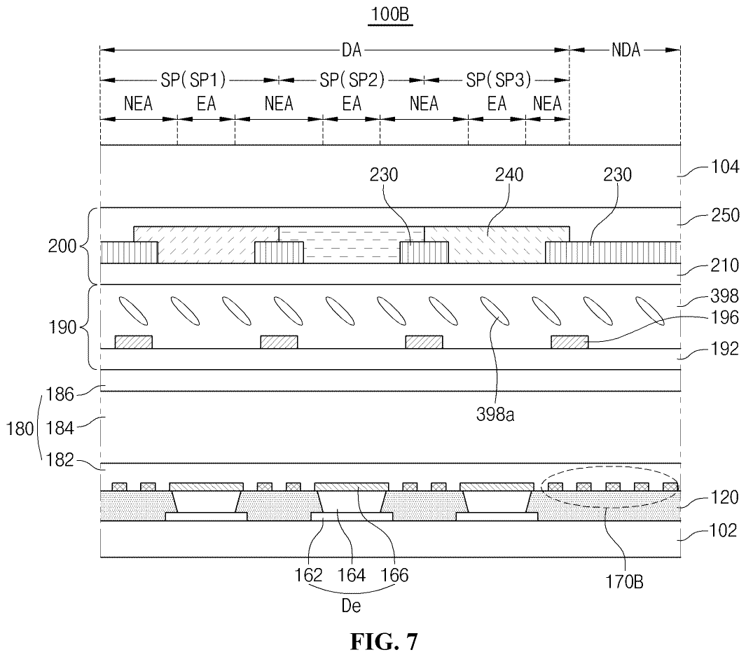

Meanwhile, the transmission axes of the first light-blocking part 170 and the second light-blocking part 230 may not coincide with each other. A display device according to a second embodiment of the present disclosure will be described with reference to FIG. 7.

FIG. 7 is a schematic cross-sectional view of a display device according to a second embodiment of the present disclosure. The display device according to the second embodiment of the present disclosure has substantially the same or similar configuration as that of the first embodiment, except for the first light-blocking part and a phase retardation layer. The same parts as those of the first embodiment are designated by the same or similar reference signs, and explanation for the same parts may be shortened or omitted.

Referring to FIG. 7, the display device 100B according to the second embodiment of the present disclosure can include the light-emitting diode De over the substrate 102, and the encapsulation layer 180, the sensor unit 190, the color unit 200, and the cover window 104 can be provided over the light-emitting diode De.

The light-emitting diode De can be disposed in the emission area EA corresponding to each sub-pixel SP of the display area DA. The pixel defining layer 120, the first light-blocking part 170B, and the second light-blocking part 230 can be provided in the non-emission area NEA of the display area DA and the non-display area NDA.

Here, the transmission axes of the first light-blocking part 170B and the second light-blocking part 230 may not coincide with each other. Specifically, the transmission axis of the first light-blocking part 170B can be perpendicular to the transmission axis of the second light-blocking part 230.

A phase retardation layer 398 can be provided between the first light-blocking part 170B and the second light-blocking part 230. In this case, the phase retardation layer 398 can be a sensor passivation layer that is provided over the sensor buffer layer 192 and the sensor electrode 196 and protects the sensor electrode. However, embodiments of the present disclosure are not limited thereto. In other embodiments, the phase retardation layer 398 can be added as a separate layer over or under the sensor unit 190.

For example, the phase retardation layer 398 can have a phase retardation of λ/2. That is, the phase retardation layer 398 can be a half wave plate (HWP) that has a phase retardation of λ/2 and changes a polarization direction of incident light. Accordingly, the linearly polarized light passing through the phase retardation layer 398 can be converted into linearly polarized light rotated by 90 degrees.

An optical axis of the phase retardation layer 398 may not coincide with the transmission axes of the first and second light-blocking parts 170B and 230. More specifically, the optical axis of the phase retardation layer 398 can have an angle of 45 degrees with respect to the transmission axes of the first and second light-blocking parts 170B and 230.

The phase retardation layer 398 can include a reactive mesogen (RM) 398a arranged in an organic material. For example, the organic material can be photosensitive acrylic polymer (photo acryl).

The reactive mesogen 398a can have a major axis and a minor axis and can be a refractive anisotropic material with a difference in the major axis refractive index nₑ and the minor axis refractive index nₒ. The major axis refractive index nₑ can be greater than the minor axis refractive index nₒ. For example, the reactive mesogen 398a can have a major axis of about 10 Å to 60 Å and a minor axis of about 5 Å to 10 Å. The major axis refractive index nₑ can be 1.6~1.8, and the minor axis refractive index nₒ can be 1.4~1.5.

The phase retardation layer 398 can be formed by applying an organic material containing reactive mesogen molecules and irradiating polarized ultra violet light thereto to thereby align and cure the reactive mesogen molecules in one direction.

Meanwhile, the phase retardation layer 398 can be formed not only in the non-emission area NEA and the non-display area NDA but also in the emission area EA. Since unpolarized light passes through the elements in the emission area EA, the phase retardation layer 398 may not affect the polarization direction of the light in the emission area EA.

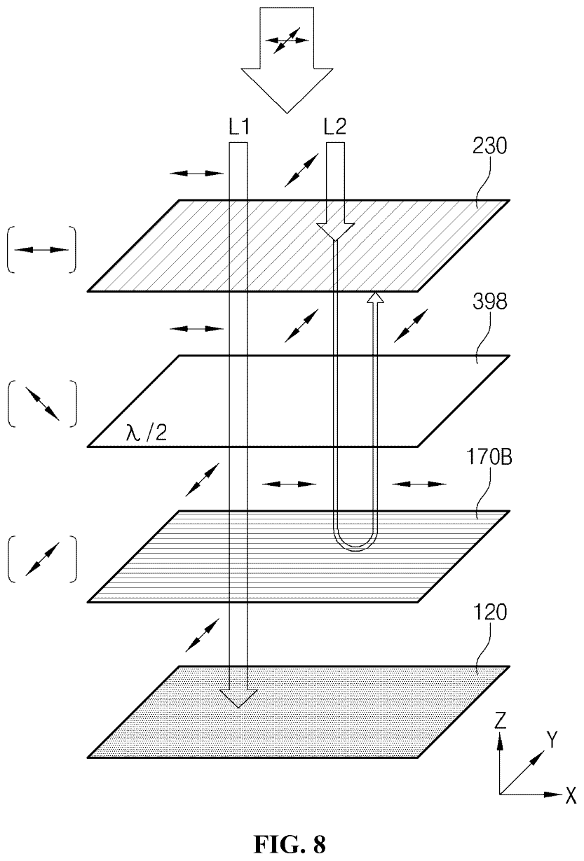

The configuration for preventing the reflection of the external light in the non-emission area NEA and the non-display area NDA of the display device 100B according to the second embodiment of the present disclosure will be described in detail with reference to FIG. 8.

FIG. 8 is a schematic view showing a path of the external light of the display device according to the second embodiment of the present disclosure and shows only the configurations that affect the path.

Referring to FIG. 8, the first light-blocking part 170B can be provided over the pixel defining layer 120, the phase retardation layer 398 can be provided over the first light-blocking part 170B, and the second light-blocking part 230 can be provided over the phase retardation layer 398.

The pixel defining layer 120 can have the light-absorbing property. The first light-blocking part 170B can selectively reflect or transmit light. The phase retardation layer 398 can change the polarization direction of light. The second light-blocking part 230 can selectively absorb or transmit light.

Here, the transmission axes of the first light-blocking part 170B and the second light-blocking part 230 can be disposed to be perpendicular to each other, and the optical axis of the phase retardation layer 398 can be disposed to have an angle of 45 degrees with respect to the transmission axes of the first light-blocking part 170B and the second light-blocking part 230. In this case, the transmission axis of the first light-blocking part 170B can be parallel to the second direction Y, and the transmission axis of the second light-blocking part 230 can be parallel to the first direction X.

For example, when the first direction X is defined as 0 degrees and the second direction Y is defined as 90 degrees, the transmission axis of the first light-blocking part 170B can be parallel to 90 degrees, the transmission axis of the second light-blocking part 230 can be parallel to 0 degrees, and the optical axis of the phase retardation layer 398 can be parallel to 135 degrees. However, embodiments of the present disclosure are not limited thereto. In other embodiments, the optical axis of the phase retardation layer 398 can be parallel to 45 degrees.

Alternatively, in other embodiments, the transmission axis of the first light-blocking part 170B can be parallel to 0 degrees, the transmission axis of the second light-blocking part 230 can be parallel to 90 degrees, and the optical axis of the phase retardation layer 398 can be parallel to 45 or 135 degrees.

Among unpolarized external light, the linearly polarized light L1 of the first direction X can coincide with the transmission axis direction of the second light-blocking part 230 and thus pass through the second light-blocking part 230, and the polarization direction of the linearly polarized light L1 can be changed into the second direction Y while passing through the phase retardation layer 398. Then, since the linearly polarized light L1 coincides with the transmission axis direction of the first light-blocking part 170B, the linearly polarized light L1 can pass through the first light-blocking part 170B and be absorbed by the pixel defining layer 120.

On the other hand, among the unpolarized external light, since the linearly polarized light L2 of the second direction Y coincides with the absorption axis direction of the second light-blocking part 230, the linearly polarized light L2 can be absorbed by the second light-blocking part 230. At this time, some of the linearly polarized light L2 may not be completely absorbed by the second light-blocking part 230 and can be changed to have the polarization direction in the first direction X while passing through the phase retardation layer 398 to thereby reach the first light-blocking part 170B. Since some of the linearly polarized light L2 coincide with the reflection axis direction of the first light-blocking part 170B, some of the linearly polarized light L2 can be reflected by the first light-blocking part 170B and can be changed to have the polarization direction in the second direction Y while passing through the phase retardation layer 398 to thereby reach the second light-blocking part 230 again. Then, some of the linearly polarized light L2 with the polarization direction in the second direction Y can coincide with the absorption axis direction of the second light-blocking part 230 and can be absorbed by the second light-blocking part 230.

Accordingly, the display device 100B according to the second embodiment of the present disclosure can include the first and second light-blocking parts 170B and 230 with different transmission axes over the pixel defining layer 120 having the light-absorbing property and can further include the phase retardation layer 398 between the first and second light-blocking parts 170B and 230 to prevent the external light from being reflected and output, thereby preventing or minimizing a decrease in the display quality and/or leakage current problems of the thin film transistor due to the reflection of the external light.

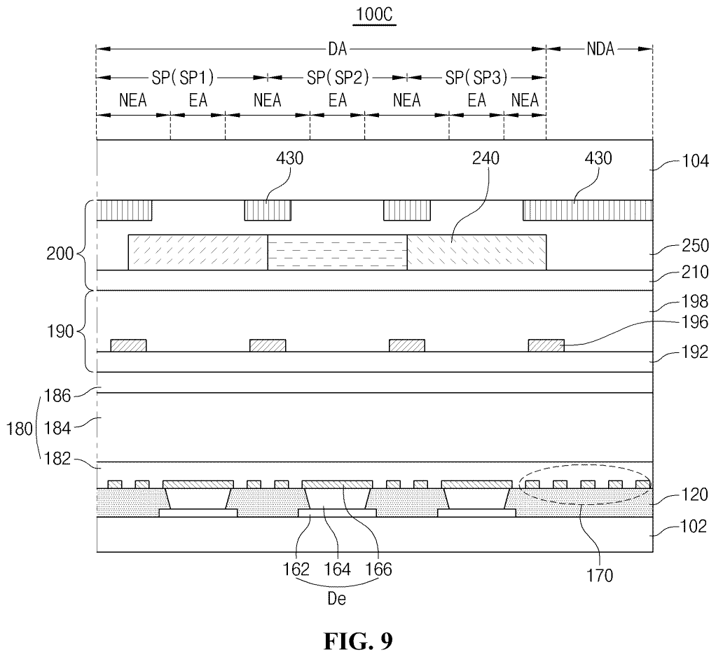

Meanwhile, the second light-blocking part 230 can be provided over the cover window 104. A display device according to a third embodiment of the present disclosure will be described with reference to FIG. 9.

FIG. 9 is a schematic cross-sectional view of a display device according to a third embodiment of the present disclosure. The display device according to the third embodiment of the present disclosure has substantially the same or similar configuration as that of the first and embodiments, except for the second light-blocking part. The same parts as those of the first and second embodiments are designated by the same or similar reference signs, and explanation for the same parts may be shortened or omitted.

Referring to FIG. 9, the display device 100C according to the third embodiment of the present disclosure can include the light-emitting diode De over the substrate 102, and the encapsulation layer 180, the sensor unit 190, the color unit 200, and the cover window 104 can be provided over the light-emitting diode De.

The light-emitting diode De can be disposed in the emission area EA corresponding to each sub-pixel SP of the display area DA. The pixel defining layer 120, the first light-blocking part 170, and the second light-blocking part 430 can be provided in the non-emission area NEA of the display area DA and the non-display area NDA.

At this time, the second light-blocking part 430 can be provided on the cover window 104. Specifically, the second light-blocking part 430 can be disposed on an inner surface of the cover window 104. An alignment layer can be further provided between the cover window 104 and the second light-blocking part 430. The second light-blocking part 430 can be spaced apart from the color filter layer 240.

Here, the transmission axes of the first light-blocking part 170 and the second light-blocking part 430 can coincide with each other. In the display device 100C according to the third embodiment of the present disclosure, the properties blocking the reflection of the external light can be substantially the same as those of FIG. 6.

In other embodiments, the transmission axes of the first light-blocking part 170 and the second light-blocking part 430 may not coincide with each other. Specifically, the transmission axis of the first light-blocking part 170 can be perpendicular to the transmission axis of the second light-blocking part 430, and the phase retardation layer having the phase retardation of λ/2 can be provided between the first light-blocking part 170 and the second light-blocking part 430.

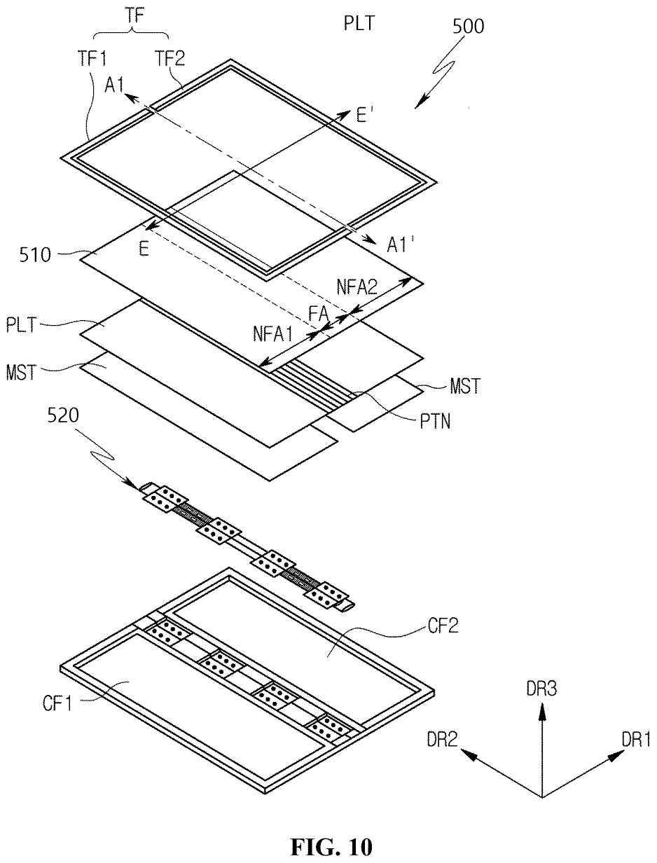

The display device according to the embodiment of the present disclosure can be applied to a foldable display device. This will be described with reference to FIGS. 10 to 12.

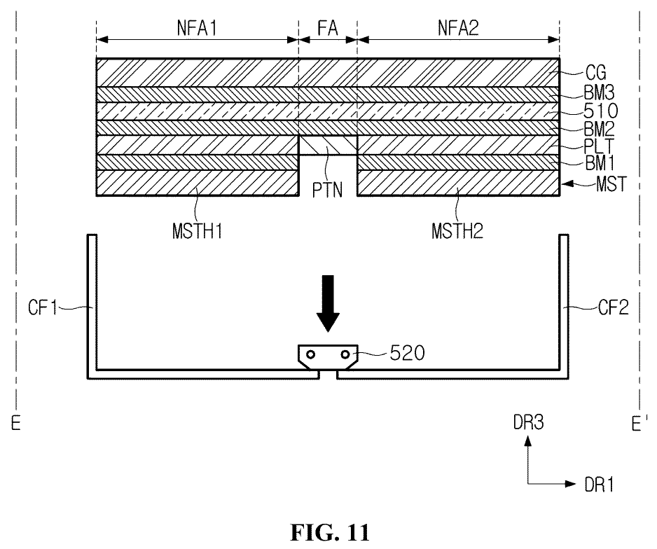

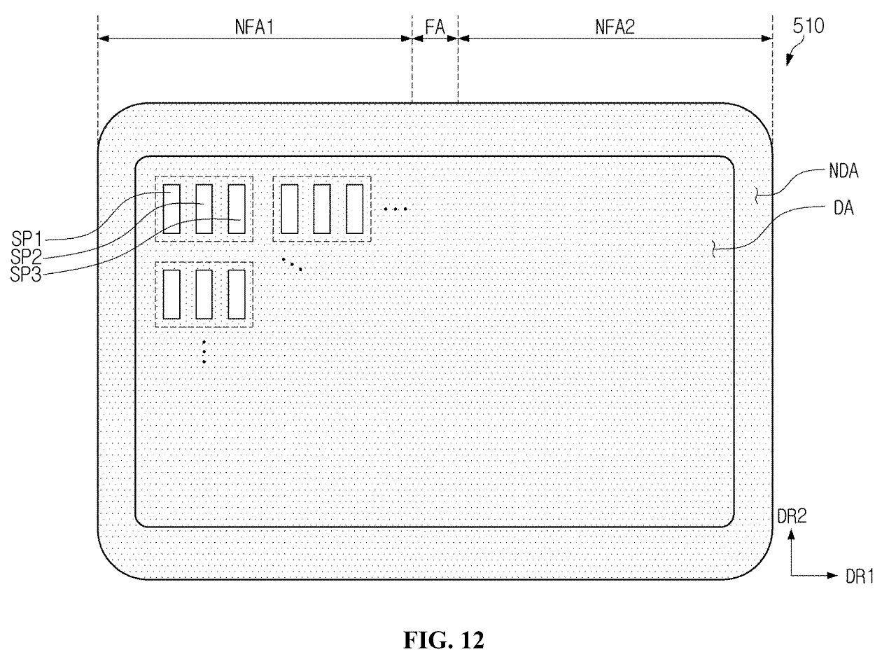

FIG. 10 is a schematic exploded perspective view of a display module according to an embodiment of the present disclosure, FIG. 11 is a schematic cross-sectional view of a display module according to an embodiment of the present disclosure, and FIG. 12 is a schematic plan view of a display module according to an embodiment of the present disclosure. FIG. 11 shows a cross-section taken along line E-E′ of FIG. 10.

Referring to FIGS. 10 to 12, the display module 500 according to the embodiment of the present disclosure can be a foldable display module, and a folding axis A1-A1′ along which the display module 500 is folded can be identical to a second direction DR2.

A top frame TF can be provided at the uppermost portion of the display module 500. The top frame TF can include a first top frame TF1 disposed on one side of the folding axis A1-A1′ and a second top frame TF2 disposed on the other side of the folding axis A1-A1′. The top frame TF can be disposed to cover the edge of the display device 510. The top frame TF can protect the display device 510 from the external impacts. The top frame TF can form a bezel of the display device 510.

A cover layer CG can be disposed under the top frame TF. The cover layer CG can be disposed over the display device 510.

By disposing the cover layer CG over the display device 510, the cover layer CG can serve to protect members disposed under the cover layer CG from the outside. The cover layer CG can be the cover window 104 of the previous embodiments.

An assembly can be disposed under the cover layer CG. The assembly can include the display device 510 and a plate PLT. The display device 510 can have a structure substantially identical to one of the display devices 100A, 100B, and 100C described with reference to FIGS. 1, 7, and 9.

The plate PLT can include various plates disposed under the display device 510 to support the display device 510. For example, one or more plates can include a back plate for supporting the display device 510, a top plate disposed under the back plate and formed of stainless steel (SUS), a bottom plate disposed under the top plate, having patterns in a folding portion, and formed of stainless steel (SUS), a heat dissipation sheet for dissipating heat, and a middle plate for covering an uneven surface due to various components of a hinge assembly.

A slit pattern PTN can be formed in the plate PLT. The slit pattern PTN can be formed at a location corresponding to a folding area FA of the display device 510. The slit pattern PTN can be an etched portion having a slit shape formed in the plate PLT. For example, the plate PLT can be formed of a metal such as stainless steel (SUS). However, the strong nature of the metal can cause problems in folding or unfolding the plate PLT. The slit pattern PTN can supplement flexibility to the plate PLT.

A middle plate MST can be disposed under the assembly. The middle plate MST can support the components positioned higher than the middle plate MST. In addition, a hinge assembly 520 and a cover frame CF1 and CF2 can be disposed under the middle plate MST, and the upper surfaces of the hinge assembly 520 and the cover frame CF1 and CF2 may be uneven. The middle plate MST can flatten the uneven surfaces thereunder. The middle plate MST can be formed of a material such as plastic, polyimide, or metal to increase the rigidity of the display module 500. For example, the middle plate MST can include aluminum or stainless steel (SUS), but embodiments of the present disclosure are not limited thereto.

The middle plate MST can include a first middle plate portion MSTH1 disposed in a first unfolding area NFA1 and a second middle plate portion MSTH2 disposed in a second unfolding area NFA2.

The hinge assembly 520 can be disposed under the assembly. The hinge assembly 520 can be disposed under the folding area FA of the display device 510. The hinge assembly 520 can have an elongated shape along the folding axis A1-A1′. The hinge assembly 520 can perform a folding motion in which one side and the other side rotate with respect to the folding axis A1-A1′.

The cover frame CF1 and CF2 can be disposed under the hinge assembly 520. A receiving groove can be formed on the upper surface of the cover frame CF1 and CF2 into which a portion of the hinge assembly 520 can be seated. The cover frame CF1 and CF2 can include a first cover frame CF1 disposed on one side and a second cover frame CF2 with respect to the folding axis A1-A1′. The cover frame CF1 and CF2 can be a housing defining the side and rear surfaces of the display module 500. The cover frame CF1 and CF2 can protect the display module from the external impacts. The cover frame CF1 and CF2 can be couple to the hinge assembly 520. Folding and unfolding of display module 500 can be implemented according to the rotation of the cover frame CF1 and CF2.

Bonding members BM1, BM2, and BM3 can be further disposed between adjacent members MST, PLT, 510, and CG. The first bonding member BM1 can connect the middle plate portion MSTH1 and MSTH2 and the plate PLT in each unfolding area NFA1 and NFA2. The second bonding member BM2 can connect the plate PLT and the display device 510. The third bonding member BM3 can connect the display device 510 and the cover layer CG.

The plate PLT, the middle plate MST, and the display device 510 coupled to each other can be mounted over the cover frame CF1 and CF2. The display module 500 can be folded and unfolded by the hinge assembly 520 arranged over the cover frame CF1 and CF2.

Embodiments of the present disclosure can provide a display device capable of being applied to a foldable product with a foldable display area and improved flexibility by omitting a polarizing plate.

Embodiments of the present disclosure can provide a display device capable of having the same reflectance and reflection visibility in the display area and the non-display area and implementing a sense of unity by providing the same configuration for blocking the reflection of the external light in the display area and the non-display area.

Embodiments of the present disclosure can provide a display device capable of achieving structural simplification by providing the same configuration for blocking the reflection of the external light in the display area and the non-display area.

Embodiments of the present disclosure can improve the reliability problem of the black bank because the first and second light-blocking parts having the different light-blocking characteristics are provided over the pixel defining layer to reduce the amount of black pigments in the pixel defining layer.

Embodiments of the present disclosure can simplify the manufacturing process by forming the first light-blocking part through the same process as the cathode electrode.

Embodiments of the present disclosure can minimize the reflection of the external light and stains caused by the reflection of the external light by disposing the pixel defining layer including a black-based material in the non-emission area of the display area and the non-display area and absorbing and blocking the external light.

Embodiments of the present disclosure can provide a low-reflection display device by including the pixel defining layer containing a black-based material, thereby having the advantage of low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
an emission area and a non-emission area;
a light-emitting diode in the emission area over the substrate and including a first electrode, a light-emitting layer, and a second electrode;
a pixel defining layer in the non-emission area over the substrate;
a first light-blocking part over the pixel defining layer; and
a second light-blocking part over the first light-blocking part,
wherein the pixel defining layer has a light-absorbing property, and
wherein each of the first light-blocking part and the second light-blocking part is configured to transmit linearly polarized light having a polarization direction that is aligned with a transmission axis direction, and to reflect or absorb linearly polarized light having a polarization direction that is perpendicular to the transmission axis direction.

2. The display device of claim 1, wherein a display area includes the emission area and the non-emission area, and a non-display area is provided on at least one side of the display area, and
wherein the pixel defining layer, the first light-blocking part, and the second light-blocking part are disposed in the non-emission area and the non-display area.

3. The display device of claim 1, wherein the first light-blocking part is configured to transmit the linearly polarized light having the polarization direction that is aligned with the transmission axis direction, and to reflect the linearly polarized light having the polarization direction that is perpendicular to the transmission axis direction, and
wherein the second light-blocking part is configured to transmit the linearly polarized light having the polarization direction that is aligned with the transmission axis direction, and to absorb the linearly polarized light having the polarization direction that is perpendicular to the transmission axis direction.

4. The display device of claim 3, wherein the transmission axis direction of the first light-blocking part and the transmission axis direction of the second light-blocking part are parallel to each other.

5. The display device of claim 3, further comprising a phase retardation layer between the first light-blocking part and the second light-blocking part,
wherein the transmission axis direction of the first light-blocking part and the transmission axis direction of the second light-blocking part are perpendicular to each other.

6. The display device of claim 5, further comprising a sensor electrode between the first light-blocking part and the second light-blocking part,
wherein the phase retardation layer is disposed between the sensor electrode and the second light-blocking part.

7. The display device of claim 5, wherein the phase retardation layer has a phase retardation of λ/ 2, and an optical axis of the phase retardation layer has an angle of 45 degrees with respect to the transmission axis directions of the first light-blocking part and the second light-blocking part, and
wherein λ is a wavelength of a light that is incident on the phase retardation layer.

8. The display device of claim 1, wherein the first light-blocking part is a wire grid polarizer.

9. The display device of claim 8, wherein the first light-blocking part is formed of a same material and on a same layer as the second electrode of the light-emitting diode.

10. The display device of claim 1, wherein the second light-blocking part includes a reactive mesogen and a dichroic dye.

11. The display device of claim 1, further comprising a thin film transistor between the substrate and the light-emitting diode and electrically connected to the light-emitting diode,
wherein the thin film transistor includes a semiconductor layer formed of an oxide semiconductor material.

12. The display device of claim 1, further comprising a first transistor electrically connected to the light-emitting diode and a second transistor between the substrate and the light-emitting diode,
wherein the first transistor includes a first semiconductor layer, and the second transistor includes a second semiconductor layer, and
wherein the first semiconductor layer and the second semiconductor layer include different materials.

13. The display device of claim 12, wherein one of the first semiconductor layer and the second semiconductor layer includes an oxide semiconductor material, and a remaining one of the first semiconductor layer and the second semiconductor layer includes polycrystalline silicon.

14. The display device of claim 12, wherein the first semiconductor layer includes an oxide semiconductor material, and the first transistor is a driving transistor connected to the light-emitting diode.

15. The display device of claim 1, wherein the pixel defining layer is a black bank.

16. The display device of claim 1, further comprising:
an encapsulation layer over the light-emitting diode and the pixel defining layer; and
a color filter layer over the encapsulation layer and corresponding to the light-emitting diode.

17. The display device of claim 16, further comprising a cover window over the second light-blocking part,
wherein the second light-blocking part is disposed between the cover window and the color filter layer.

18. The display device of claim 1, further comprising:
an encapsulation layer over the light-emitting diode and the pixel defining layer; and
a sensor unit over the encapsulation layer.
